(19) United States
(12) Patent Application Publication
(10) Pub. No.: US 2020/0091196 A1
(43) Pub. Date: Mar. 19, 2020

(54) THIN-FILM TRANSISTOR SUBSTRATE, METHOD FOR MANUFACTURING SAME, AND LIQUID CRYSTAL DISPLAY

(71) Applicant: Mitsubishi Electric Corporation, Tokyo (JP)

(72) Inventors: Tsutomu MATSUURA, Kumamoto (JP); Kazunori INOUE, Kumamoto (JP)

(73) Assignee: Mitsubishi Electric Corporation, Tokyo (JP)

(21) Appl. No.: 16/570,840

(22) Filed: Sep. 13, 2019

(30) Foreign Application Priority Data
Sep. 19, 2018 (JP) 2018-175120

(51) Int. Cl. H01L 27/12; G02F 1/1362

(52) U.S. Cl. CPC H01L 27/124; H01L 27/1218; G02F 1/136277; H01L 27/127

(57) ABSTRACT

A TFT substrate is provided with a pixel TFT and a drive-circuit TFT disposed on a substrate. The pixel TFT includes a source electrode and a drain electrode that are disposed on the surface of the semiconductor layer and separated from each other. The drive-circuit TFT includes an etch stopper layer disposed on the semiconductor layer, and a source electrode and a drain electrode that are disposed on the surfaces of the etch stopper layer and the semiconductor layer and separated from each other.

### BACKGROUND OF THE INVENTION

### Field of the Invention

The present invention relates to a thin-film transistor substrate, a method for manufacturing the same, and a liquid crystal display.

### Description of the Background Art

A TFT active matrix substrate (hereinafter referred to as “TFT substrate”), in which thin-film transistors (hereinafter referred to as “TFTs”) are arranged in an array form as switching devices, has been used for an electro-optical device such as a liquid crystal display (hereinafter referred to as “LCD”).

A semiconductor device typified by the TFT is characterized by low power consumption and thinness. Taking advantage of such characteristics of the semiconductor device, application to a flat panel display has been made in place of a cathode ray tube (CRT).

In an LCD used for the flat panel display, a liquid crystal layer is generally provided between a TFT substrate and a counter substrate. A polarizing plate is provided on each of the outer surfaces of the TFT substrate and the counter substrate as thus described, and in each of a transmissive and a semi-transmissive LCD, a backlight unit is provided on the far outside of the polarizing plate of the TFT substrate or the counter substrate. Further, in a color display LCD, for example, a color filter of one color or two or more colors is provided on the counter substrate, and a favorable color display can be obtained.

Conventionally, amorphous silicon (Si) has generally been used as a semiconductor active layer (channel layer) in a switching device of the TFT substrate for the liquid crystal display. However, in recent years, the development of a TFT in which an oxide semiconductor is used for the active layer has been conducted actively.

The oxide semiconductor has higher mobility than amorphous silicon and thus has the advantage of being able to achieve a small and high-performance TFT. As the oxide semiconductor, a zinc oxide (ZnO)-based material and a material obtained by adding gallium oxide (Ga₂O₃), indium oxide (In₂O₃), tin oxide (SnO₂), or the like to zinc oxide are mainly used.

In the TFT using this oxide semiconductor layer, the layer can be formed at a relatively low temperature by sputtering or the like and is easier to produce than a TFT using a semiconductor layer made of polycrystalline silicon (poly-Si). In a case where the TFT using the oxide semiconductor layer is applied to an LCD, not only a pixel TFT constituting a pixel but also a drive circuit can be integrally formed on the TFT substrate.

Meanwhile, the operation reliability of the drive circuit and the performance of the display depend on the electric characteristics of the drive-circuit TFT, and a threshold voltage is particularly important among those characteristics. A space-saving design has been achieved in the drive circuit in response to the demand for narrowing the frame of the display, but as a result, it is often impossible to apply a negative gate voltage to the drive-circuit TFT. As thus described, when the threshold voltage of the drive-circuit TFT is a negative voltage value, it is difficult to control the drive circuit. In this case, a so-called normally-on state occurs where a current flows between a source electrode and a drain electrode even when a gate voltage is 0 V, and power consumption increases. Therefore, the drive-circuit TFT preferably has a characteristic in which the threshold voltage is a positive voltage value.

On the other hand, the negative gate voltage can be applied to the pixel TFT, and the normally-on state is somewhat acceptable, so that a TFT, the threshold voltage of which is a negative voltage value, can also be applied. The TFT, the threshold voltage of which is a negative voltage value, has characteristics in which a sub-threshold coefficient (S value) is small and an on-current value is sufficiently large as compared to the TFT with the threshold voltage being a positive voltage value. Therefore, the pixel TFT preferably has a characteristic in which the threshold voltage is a negative voltage value.

As described above, since the required electric characteristics are different between the pixel TFT and the drive-circuit TFT, it is preferable to differently produce these TFTs in accordance with the respectively required electric characteristics. Under such circumstances, a configuration of a TFT substrate, where a plurality of types of TFTs having different electric characteristics can be prepared on the same substrate, has been proposed (e.g., International Publication No. WO 2013/080516).

In the case of manufacturing the TFT substrate disclosed in Patent Document 1, an oxidizing action and a reducing action are exerted on an oxide semiconductor by a process after formation of a source electrode and a drain electrode, to control a threshold voltage. However, in such a technique, it is difficult to form TFTs having different threshold voltages on the same substrate with high reproducibility by a common process.

### SUMMARY

The present invention has been made in view of the above problems, and an object of the present invention is to provide a technique capable of forming, in a thin-film transistor using an oxide semiconductor, TFTs having different threshold voltages can be formed on the same substrate with high reproducibility by a common process.

According to the present invention, the thin-film transistor substrate includes a first thin-film transistor and a second thin-film transistor disposed on a substrate. The first thin-film transistor includes a first gate electrode disposed on the substrate, a first gate insulating film covering the first gate electrode, a first oxide semiconductor layer facing the first gate electrode via the first gate insulating film, a first source electrode and first drain electrode that are disposed on a surface of the first oxide semiconductor layer and separated from each other, and a first insulating film disposed on the first oxide semiconductor layer, the first source electrode, and the first drain electrode. The second thin-film transistor includes a second gate electrode disposed on the substrate, a second gate insulating film covering the second gate electrode, a second oxide semiconductor layer facing the second gate electrode via the second gate insulating film, a second insulating film disposed on the second oxide semiconductor layer, and a second source electrode and a second drain electrode that are disposed on surfaces of the second insulating film and the second oxide semiconductor layer and separated from each other.

The TFTs with different threshold voltages can be formed on the same substrate with high reproducibility by a common process.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view schematically illustrating a configuration of a liquid crystal display;

FIG. 2 is a plan view schematically illustrating an entire configuration of a TFT substrate according to a preferred embodiment;

FIG. 3 is a plan view illustrating a planar configuration of a pixel according to the preferred embodiment;

FIG. 4 is a cross-sectional view illustrating a cross-sectional configuration of a TFT substrate according to the preferred embodiment;

FIG. 5 is a circuit diagram illustrating one mode of a scanning signal drive circuit;

FIG. 6 is a timing chart illustrating an operation of one mode of the scanning signal drive circuit;

FIGS. 7 to 14 are cross-sectional views each illustrating the manufacturing process of the TFT substrate according to the preferred embodiment;

FIG. 15 is a diagram illustrating drain current-gate voltage dependency of a TFT substrate according to an example of the preferred embodiment;

FIG. 16 is a diagram illustrating drain current-gate voltage dependency of a TFT substrate according to a comparative example;

FIG. 17 is a diagram illustrating channel widths and channel lengths of the example and the comparative example;

FIG. 18 is a diagram illustrating film forming conditions and film characteristics of etch stopper layers and protective insulating films of the example and the comparative example;

FIGS. 19 and 20 are cross-sectional views each illustrating a cross-sectional configuration of a TFT substrate according to a first modification;

FIG. 21 is a view illustrating drain current-gate voltage dependency of a TFT substrate according to the example of the first modification; and

FIG. 22 is a cross-sectional view illustrating the manufacturing process of the TFT substrate according to a second modification.

### DESCRIPTION OF THE PREFERRED EMBODIMENT

<Configuration of Liquid Crystal Display>

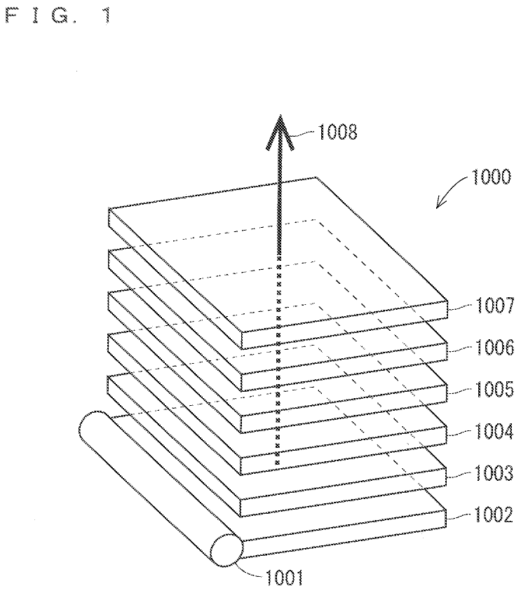

FIG. 1 is a perspective view schematically illustrating a configuration of a liquid crystal display 1000 provided with a TFT substrate. The configuration of the liquid crystal display 1000 will be described below with reference to FIG. 1.

As illustrated in FIG. 1, the liquid crystal display 1000 is provided with a light source 1001, a light guide plate 1002, a polarizing plate 1003, a TFT substrate 1004, a liquid crystal layer 1005, a counter substrate 1006, and a polarizing plate 1007.

The light source 1001 is a light source of the liquid crystal display 1000, and for example, a light-emitting diode or the like is used. The planar light guide plate 1002 guides light incident from the light source 1001 provided outside the one end face of the light guide plate 1002 so that the light is emitted from the entire main surface of the light guide plate 1002. The light source 1001 and the light guide plate 1002 may be collectively referred to as a backlight unit.

The polarizing plate 1003, the TFT substrate 1004, the liquid crystal layer 1005, the counter substrate 1006, and the polarizing plate 1007 are disposed in this order on the main surface on the light emission side of the light guide plate 1002. As thus described, the liquid crystal layer 1005 is sandwiched between the counter substrate 1006 and the TFT substrate 1004.

Here, an outline of the operation of the liquid crystal display 1000 will be described. The TFT provided on the TFT substrate 1004 controls the polarization direction of the liquid crystal in the liquid crystal layer 1005 by controlling an electric field applied to the liquid crystal layer 1005 in accordance with signals from the outside and the drive circuit. In such a configuration where the TFT substrate 1004 is combined with the polarizing plate 1003, the liquid crystal layer 1005, the counter substrate 1006, and the polarizing plate 1007, the transmission or the shielding of light 1008 emitted from the light guide plate 1002 is controlled for each pixel so that the liquid crystal display 1000 can display a desired image.

### Preferred Embodiment

The TFT substrate according to the preferred embodiment of the present invention will be described as an active matrix substrate in which TFTs are arranged in a matrix form as switching devices. The TFT substrate according to the present preferred embodiment is used for a planar panel display (flat panel display) represented by a liquid crystal display, as is the TFT substrate 1004 in FIG. 1.

<Entire Configuration of TFT Substrate>

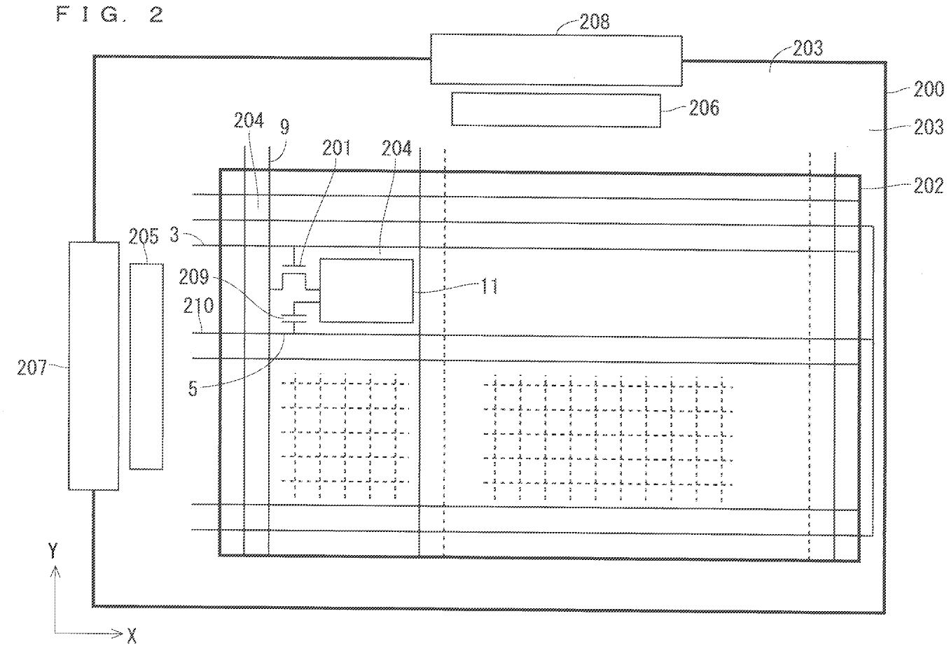

FIG. 2 is a plan view schematically illustrating the entire configuration of a TFT substrate 200 (corresponding to the TFT substrate 1004 in FIG. 1) according to the present preferred embodiment, and here, an example of a TFT substrate for LCD is illustrated.

The TFT substrate 200 illustrated in FIG. 2 is a TFT array substrate, in which pixel TFTs 201 are arranged in a matrix form, and is roughly divided into a display area 202 and a frame area 203 provided so as to surround the display area 202.

In the display area 202, a plurality of gate lines (scanning signal lines) 3, a plurality of auxiliary capacitance wires 210, and a plurality of source wires (display signal lines) 9 are arranged. The plurality of gate wires 3 are arranged in parallel to one another, and the plurality of source wires 9 are arranged in parallel to one another so as to cross the plurality of gate wires 3 at right angles. In FIG. 2, the gate wire 3 is disposed to extend in the lateral direction (X-direction), and the source wire 9 is disposed to extend in the vertical direction (Y-direction).

Then, an area surrounded by the two adjacent gate wires 3 and the two adjacent source wires 9 becomes a pixel 204, so that the pixels 204 are arranged in a matrix form in the TFT substrate 200.

In FIG. 2, the configuration of a part of the pixels 204 is illustrated in an enlarged manner, and at least one pixel TFT 201 is disposed in the pixel 204. The pixel TFT 201 is disposed near the intersection of the source wire 9 and the gate wire 3, the gate electrode of the pixel TFT 201 is connected to the gate wire 3, and the source electrode of the pixel TFT 201 is connected to the source wire 9. The drain electrode of the pixel TFT 201 is connected to a transmissive pixel electrode (pixel electrode) 11 that constitutes a pixel part in cooperation with the pixel TFT 201. Further, an auxiliary capacitance 209 is connected to the transmissive pixel electrode 11, and an auxiliary capacitance wire 210 provided in parallel with each of the plurality of gate wires 3 also serves as an auxiliary capacitance electrode 5 forming the auxiliary capacitance 209.

A scan signal drive circuit 205 and a display signal drive circuit 206 are provided in the frame area 203 of the TFT substrate 200. The gate wire 3 extends from the display area 202 to the frame area 203 on the side where the scanning signal drive circuit 205 is provided, and the gate wire 3 is connected to the scanning signal drive circuit 205 at the end of the TFT substrate 200.

Similarly, the source wire 9 extends from the display area 202 to the frame area 203 on the side where the display signal drive circuit 206 is provided, and the source wire 9 is connected to the display signal drive circuit 206 at the end of the TFT substrate 200.

Further, a connection board 207 connected to the outside is disposed near the scanning signal drive circuit 205, and a connection board 208 connected to the outside is disposed near the display signal drive circuit 206. Each of the connection boards 207, 208 is, for example, a wiring board such as a flexible printed circuit (FPC).

Various signals from the outside are supplied to the scanning signal drive circuit 205 and the display signal drive circuit 206 via the connection boards 207, 208, respectively. The scanning signal drive circuit 205 supplies a gate signal (scanning signal) to the gate wire 3 based on a control signal from the outside. The gate wire 3 is sequentially selected by this gate signal. The display signal drive circuit 206 supplies a display signal to the source wire 9 based on a control signal and display data from the outside Thereby, a display voltage corresponding to the display data is supplied to each pixel 204.

The display signal drive circuit 206 is not limited to the configuration disposed on the TFT substrate 200, and for example, the drive circuit may be formed of a tape carrier package (TCP) and disposed in a portion different from the TFT substrate 200.

In addition, as will be described later using a plan view, the auxiliary capacitance wire 210 is provided such that a part thereof overlaps (superimposes) the transmissive pixel electrode 11 in a plan view, and then, the auxiliary capacitance 209 is formed with the transmissive pixel electrode 11 as one electrode and with a part of the auxiliary capacitance wire 210 as the other electrode. The auxiliary capacitance wire 210 in a portion superimposed with the transmissive pixel electrode 11 functions as the auxiliary capacitance electrode 5. All the auxiliary capacitance wires 210 are electrically bundled on the outside of the display area 202, and for example, a common potential is supplied from the display signal drive circuit 206.

The pixel TFT 201 functions as a switching device for supplying a display voltage to the transmissive pixel electrode 11, and the on/off of the pixel TFT 201 is controlled by the gate signal input from the gate wire 3. When a predetermined voltage is applied to the gate wire 3 and the pixel TFT 201 is turned on, a current flows from the source wire 9 to the drain electrode. Thereby, the display voltage is applied from the source wire 9 to the transmissive pixel electrode 11 connected to the drain electrode of the pixel TFT 201, and an electric field corresponding to the display voltage is generated between the transmissive pixel electrode 11 and a counter electrode (not illustrated). A liquid crystal capacitance (not illustrated) formed of liquid crystal is electrically connected in parallel with the auxiliary capacitance 209 between the transmissive pixel electrode 11 and the counter electrode. In the case of an in-plane switching liquid crystal display and a fringe-field-switching (FFS) liquid crystal display, the counter electrode is disposed on the TFT substrate 200 side.

The display voltage applied to the transmissive pixel electrode 11 is held by the liquid crystal capacitance and the auxiliary capacitance 209 for a certain period. An alignment film (not illustrated) may be disposed on the surface of the TFT substrate 200.

Further, as described with reference to FIG. 1, a counter substrate such as a counter substrate 1006 is disposed facing the TFT substrate 200. The counter substrate is, for example, a color filter substrate and is disposed on the viewing side. A color filter, a black matrix (BM), an alignment film, and the like are disposed on the counter substrate, and the counter electrode is also disposed on the counter substrate depending on the system of the liquid crystal display.

Then, as described with reference to FIG. 1, the TFT substrate 1004 and the counter substrate 1006, that is, the TFT substrate 200 and the counter substrate, are bonded to each other via a certain gap (cell gap), and liquid crystal is injected into the gap between these substrates to seal the gap. That is, the liquid crystal layer 1005 is disposed between the TFT substrate 1004 and the counter substrate 1006. Further, polarizing plates 1003, 1007, a retardation plate, and the like are provided on the outer surfaces of the TFT substrate 1004 and the counter substrate 1006. Moreover, on the opposite side to the viewing side of the liquid crystal display configured as described above, a backlight unit or the like including the light source 1001 and the light guide plate 1002 is disposed.

<Operation of Liquid Crystal Display>

The operation of the liquid crystal display 1000 will be described in detail with reference to FIGS. 1 and 2. When the liquid crystal of the liquid crystal layer 1005 is driven by the electric field between the transmissive pixel electrode 11 and the counter electrode, the alignment direction of the liquid crystal of the liquid crystal layer 1005 is changed. Thereby, the polarization state of light passing through the liquid crystal layer 1005 changes. That is, the polarization state of light, which passes through the liquid crystal layer 1005 after being linearly polarized by passing through the polarizing plate 1003, also changes. Specifically, light from the backlight unit is linearly polarized by the polarizing plate 1003 on the TFT substrate 1004 side. Then, by the linearly polarized light passing through the liquid crystal layer 1005, the polarization state of the linearly polarized light changes.

Therefore, the amount of light passing through the polarizing plate 1007 on the side of the counter substrate 1006 changes depending on the polarization state and hence the electric field described above. That is, the amount of light 1008 passing through the polarizing plate 1007 on the viewing side can be changed by the electric field described above, light 1008 being of the transmitted light transmitted from the backlight unit through the liquid crystal display. In such a configuration, by controlling the display voltage for each pixel, a desired image can be displayed on the liquid crystal display.

<Detailed Configuration of TFT Substrate>

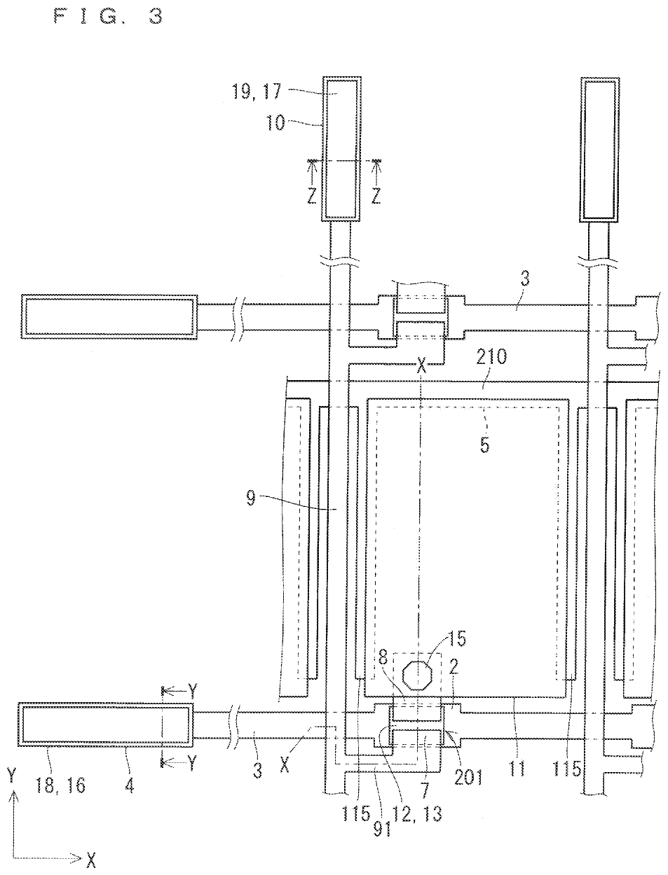

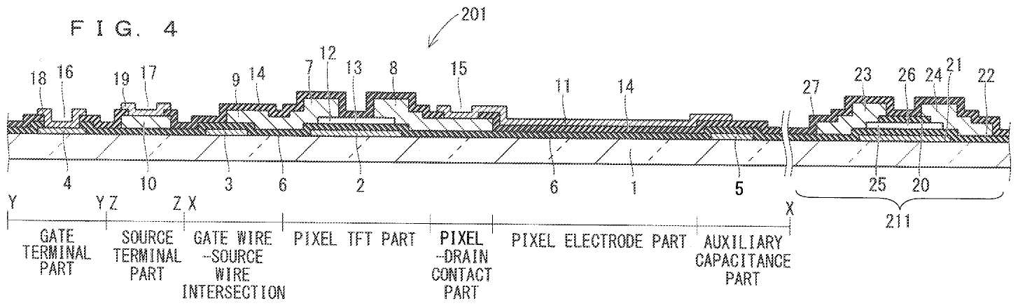

Next, a configuration of the TFT substrate 200 of the present preferred embodiment will be described with reference to FIGS. 3 and 4. FIG. 3 is a plan view illustrating a plan configuration of the pixel 204 illustrated in FIG. 2, and FIG. 4 is a cross-sectional view illustrating a cross-sectional configuration taken along line XX in FIG. 3 (a cross-sectional configuration of a gate wire—source wire intersection, a pixel TFT part, a pixel—drain contact part, a pixel electrode part, and an auxiliary capacitance part), a cross-sectional configuration taken along line YY in FIG. 3 (a cross-sectional configuration of a gate terminal part), a cross-sectional configuration taken along line ZZ in FIG. 3 (a cross-sectional configuration of a source terminal part), and a drive-circuit TFT 211 in the scan signal drive circuit 205. In the following, the TFT substrate 200 will be described as being used for a transmissive liquid crystal display.

As illustrated in FIGS. 3 and 4, the pixel TFT 201 which is a first thin-film transistor and a drive-circuit TFT 211 which is a second thin-film transistor are disposed on a substrate 1. As will be apparent from the following description, the gate threshold of the pixel TFT 201 is a negative threshold, and the gate threshold of the drive-circuit TFT 211 is a positive threshold. Hereinafter, the configurations of the pixel TFT 201 and the drive-circuit TFT 211 will be described in this order.

<Configuration of Pixels in TFT Substrate>

As illustrated in FIG. 3, the gate wire 3, a part of which constitutes a gate electrode 2, is disposed to extend in the X-direction, and the auxiliary capacitance wire 210, a part of which constitutes the auxiliary capacitance electrode 5, is disposed to extend in the X-direction in parallel to the gate wire 3. Further, a branch wire 91 extending in the X-direction is branched from the source wire 9 extending in the Y-direction, and a tip portion of the branch wire 91, which is superimposed on the gate electrode 2, is a source electrode 7.

The transmissive pixel electrode 11 is provided in a pixel area surrounded by two adjacent gate wires 3 and two adjacent source wires 9, and the transmissive pixel electrode 11 is connected to the drain electrode 8.

A portion of the gate wire 3 where the wire width is greater than those of the other portions functions as the gate electrode 2, and a semiconductor layer 12 made of an oxide semiconductor is disposed on the gate electrode 2, and the source electrode 7 and the drain electrode 8 are disposed on the surface of the semiconductor layer 12 while being separated from each other. These constitute the pixel TFT 201. During the operation of the pixel TFT 201, a channel part 13 is formed in the semiconductor layer 12 between the source electrode 7 and the drain electrode 8.

In one pixel area, the auxiliary capacitance wire 210 has two branch wires 115 extending in the Y-direction. The two branch wires 115 are respectively provided in portions corresponding to two edges on the source wire 9 side in the pixel area and configured such that the portion of the auxiliary capacitance wire 210 to be the auxiliary capacitance electrode 5 and the branch wires 115 are formed in the shape of the letter II (Pi) in a plan view. Then, the auxiliary capacitance 209 (FIG. 2) is formed between the auxiliary capacitance electrode 5 or branch wires 115 and the transmissive pixel electrode 11 superimposed thereon. The shape formed by the auxiliary capacitance electrode 5 and the branch wires 115 is not limited to the shape of H and may be linear or L-shaped as long as a desired auxiliary capacitance can be obtained.

Each end of the gate wire 3 extending to the frame area 203 is a gate terminal 4, and is connected to a gate terminal pad 18 via a gate-terminal contact hole 16. The gate terminal pad 18 is electrically connected to the scanning signal drive circuit 205 (FIG. 2), and the scanning signal drive circuit 205 can supply a scanning signal to the gate wire 3.

Similarly, each end of the source wire 9 extending to the frame area 203 is a source terminal 10, and is connected to a source terminal pad 19 via a source-terminal contact hole 17. A video signal (display signal) from the outside is supplied to the source terminal 10 via the source terminal pad 19.

Further, all the auxiliary capacitance wires 210 are electrically bundled in the frame area 203, and a common potential is applied.

Next, the cross-sectional configuration of the pixel 204 will be described with reference to FIG. 4. As illustrated in FIG. 4, the TFT substrate 200 includes, for example, a substrate 1 which is a transparent insulating substrate such as glass or plastic, and the gate electrode (first gate electrode) 2, the gate wire 3, the gate terminal 4, and the auxiliary capacitance electrode 5 which are formed of the same conductive film and selectively disposed on the substrate 1.

The gate electrode 2, the gate wire 3, the gate terminal 4, and the auxiliary capacitance wire 210 are formed of a single layer film or multilayer film using, for example, aluminum (Al), chromium (Cr), copper (Cu), molybdenum (Mo), or an alloy in which another element is added in a small amount to these.

And the insulating film 6 which covers these is disposed. Since the insulating film 6 functions as a gate insulating film in the portion of the pixel TFT 201, the insulating film 6 may be referred to as a gate insulating film (first gate insulating film) 6. The gate insulating film 6 is formed of a laminated film of a silicon nitride film and a silicon oxide film disposed thereon.

As illustrated in the pixel TFT part of FIG. 4, in the placement area of the pixel TFT 201, the semiconductor layer (first oxide semiconductor layer) 12 facing the gate electrode 2 via the gate insulating film 6 is provided. Here, the semiconductor layer 12 is disposed on the gate insulating film 6 so as to overlap the gate electrode 2 in a plan view and is configured to be held within above the gate electrode 2.

The semiconductor layer 12 is made of an oxide semiconductor, and it is possible to use an oxide semiconductor containing at least indium (In) or zinc (Zn), such as zinc oxide (ZnO), indium oxide (In₂O₃), or an In—Zn—O-based oxide semiconductor mixed with ZnO. In addition to indium and zinc, other metals may be added. The other metals include Al (aluminum), Ti (titanium), Ga (gallium), Ge (germanium), Y (yttrium), Zr (zirconium), Si (silicon), Sn (tin), La (lanthanum), Ce (cerium), and Hf (hafnium), and one or more of these metals may be added. For example, the semiconductor layer 12 may be formed of an In—Ga—Zn—O-based oxide semiconductor in which Ga is added to the In—Zn—O-based oxide semiconductor.

The conductivity of the oxide semiconductor layer (semiconductor layer 12) of the present preferred embodiment is, for example, 1×10⁻⁷ to 10 S/cm. The carrier density of the oxide semiconductor layer is, for example, in the range of 1×10¹¹ to 1×10¹⁸/cm³. When the conductivity is higher than 10 S/cm, or when the carrier density is higher than 1×10¹⁸/cm³, electricity may easily flow at all times, and the semiconductor layer may not exhibit a switching function. It is more preferable that at the time of device preparation, the conductivity of the oxide semiconductor layer be, for example, in the range of 1×10⁻⁴ to 10¹⁰ S/cm, or the carrier density be in the range of 1×10¹² to 1×10¹⁶/cm³.

The carrier density range is high as compared to that of a semiconductor layer 25 in the drive-circuit TFT 211 described later. This is because in the pixel TFT 201 which is a back-channel type TFT, the process damage due to film formation, patterning, annealing, or the like is caused to the channel part 13 of the semiconductor layer 12 when the source electrode 7 and the drain electrode 8 are formed, and hence the carrier density of the pixel TFT 201 easily increases as compared to that of the drive-circuit TFT 211 which is an etch-stopper type TFT.

That is, by forming the back-channel type TFT, an oxide semiconductor layer having a high carrier density as compared to that of the etch-stopper type TFT can be prepared stably. By using such an oxide semiconductor layer with a high carrier density as a channel layer, a TFT in the normally-on state can be stably prepared as the pixel TFT 201. In addition, a TFT having higher mobility than amorphous silicon can be achieved, and the operation speed can be improved.

On the surface of the semiconductor layer 12, the source electrode (first source electrode) 7 and the drain electrode (first drain electrode) 8 which are made of a conductive film and are separated from each other are disposed. Thus, each of the source electrode 7 and the drain electrode 8 is connected to the semiconductor layer 12. At the time of operation of the pixel TFT 201, the channel part 13 is formed in the semiconductor layer 12 between the source electrode 7 and the drain electrode 8.

Further, on the channel part 13 of the semiconductor layer 12, the source electrode 7, and the drain electrode 8 in the pixel TFT part, on the source wire 9 and the branch wire 91 in the gate wire—source wire intersection, and on the source terminal 10 in the source terminal part, a protective insulating film (first insulating film) 14 is disposed, and the channel part 13 and the like are covered with the protective insulating film 14. The protective insulating film 14 covers the gate insulating film 6 in the gate terminal part, and also covers the gate insulating film 6 in the pixel electrode part and the auxiliary capacitance part.

In the pixel electrode part, the transmissive pixel electrode 11 formed of a transparent conductive film is formed on the protective insulating film 14. The transmissive pixel electrode 11 is connected to the drain electrode 8 via a pixel drain contact hole 15 that penetrates the protective insulating film 14 and reaches the drain electrode 8. The transmissive pixel electrode 11 extends from above the pixel drain contact hole 15 to the upper side of the auxiliary capacitance electrode 5, and an auxiliary capacitance 209 (FIG. 2) is formed between the transmissive pixel electrode 11 and the auxiliary capacitance electrode 5 (including the branch wire 115).

In the source terminal part, the source terminal pad 19 is connected to the source terminal 10 via the source-terminal contact hole 17 that penetrates the protective insulating film 14 and reaches the source terminal 10. The source terminal pad 19 is electrically connected to the display signal drive circuit 206 (FIG. 2), and the display signal drive circuit 206 can supply a display signal to the source wire 9.

In the gate terminal part, gate terminal pad 18 is connected to gate terminal 4 via gate-terminal contact hole 16 that penetrates the protective insulating film 14 and the gate insulating film 6 and reaches the gate terminal 4. The gate terminal pad 18 is electrically connected to the scanning signal drive circuit 205 (FIG. 2), and the scanning signal drive circuit 205 can supply a scanning signal to the gate wire 3.

<Configuration of Drive Circuit in TFT Substrate>

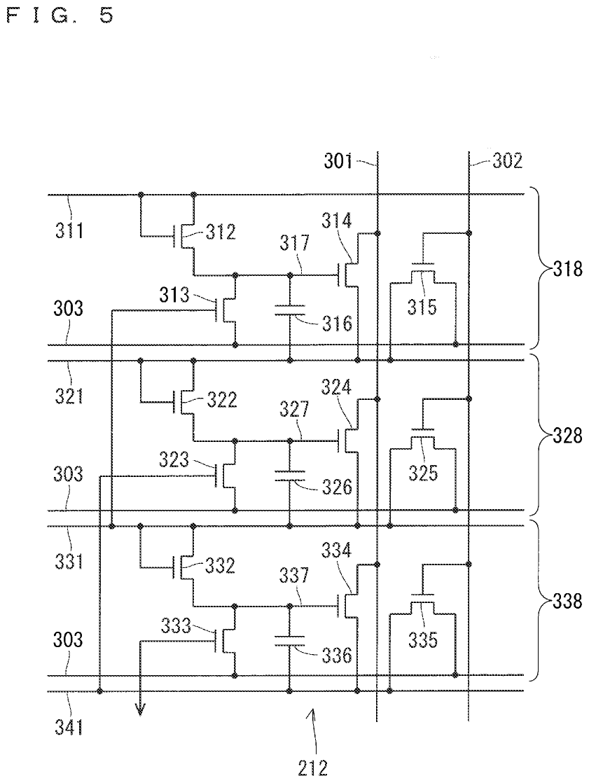

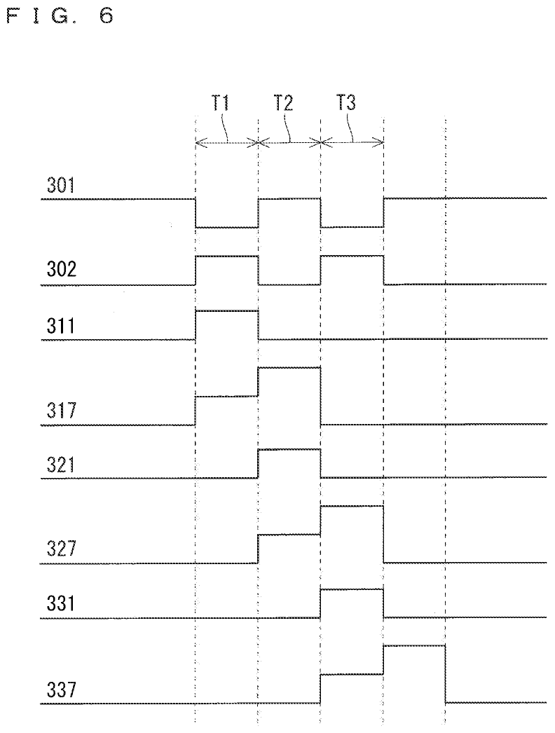

One mode of a shift register used for a part of the scan signal drive circuit 205 will be described with reference to FIGS. 5 and 6. One mode of the shift register which is used for part of the scan signal drive circuit 205 can also be used for the display signal drive circuit 206.

The scan signal drive circuit 205 has a shift register 212 including scan drive circuits 318, 328, 338. The scan signal drive circuit 205 may also have a level shifter, a buffer, or the like. In the scanning signal drive circuit, a clock signal and a start pulse signal (not illustrated) are input from clock signal lines 301, 302 to the shift register 212 to generate a selection signal. The generated selection signal is buffered and amplified in a buffer and supplied to the corresponding gate wire 3 (gate lines 311, 321, 331, 341). The gate electrodes of the pixel TFTs 201 for one line are connected to the gate lines 311, 321, 331, 341, respectively. Then, a buffer capable of allowing a large current to flow is used so that the pixel TFTs 201 for one line can be turned on simultaneously.

As an example, FIG. 5 illustrates a pulse output circuit, and FIG. 6 illustrates a timing chart of the shift register 212 provided with a plurality of pulse output circuits illustrated in FIG. 5. Although FIGS. 5 and 6 illustrate three-stage pulse output circuits, the number of stages of pulse output circuits is not limited to three. In general, the number of stages of the shift register corresponds to the number of scanning lines.

The shift register 212 is provided with TFTs 312, 322, 332, TFTs 313, 323, 333, TFTs 314, 324, 334, TFTs 315, 325, 335, and capacitances 316, 326, 336. The TFTs 312, 322, 332 are TFTs for pre-charging the internal nodes 317, 327, 337 of the shift register 212. The TFTs 313, 323, 333 are TFTs for discharging the charges of the internal nodes 317, 327, 337. The TFTs 314, 324, 334 are TFTs for supplying signals to the gate lines 311, 321, 331. The TFTs 315, 325, 335 are TFTs for holding the potentials of the gate lines 321, 331, 341. Capacitances 316, 326, 336 are disposed between the internal nodes 317, 327, 337 and the gate lines 321, 331, 341.

Further, the clock signal lines 301, 302 for driving the shift register 212 and a low potential (VSS) wire 303 are connected to the shift register 212. A high potential (VDD) and a low potential (VSS) are alternately input into the clock signal lines 301, 302 every gate selection period.

As illustrated in FIG. 6, first, in a gate selection period T1, a gate signal is input into the TFT 312 constituting the scan drive circuit 318 from the scan drive circuit (not illustrated) one row before the scan drive circuit 318. The gate line 311 is at the high potential (VDD) in the gate selection period T1. Therefore, the TFT 312 is turned on, and the internal node 317 is pre-charged. At this time, the TFT 314 is turned on, and the TFT 315 is also turned on since the clock signal line 302 is at the high potential (VDD), but the gate line 321 is charged with the low potential (VSS) since the clock signal line 301 is at the low potential (VSS).

In the next gate selection period T2, the clock signal line 301 is switched to the high potential (VDD), and the clock signal line 302 is switched to the low potential (VSS). At this time, since the TFT 314 is in the on-state and the TFT 315 is in the off-state, the gate line 321 is charged with the high potential (VDD) of the clock signal line 301. While the gate line 321 is charged, the internal node 317 is pushed up to a higher potential via the capacitance 316, and a sufficiently high voltage for charging the gate line with the high potential (VDD) can be applied to the gate electrode of the TFT 314. Further, during this period, the signal of the gate line 321 is input into the scan drive circuit 328, the TFT 322 is turned on, and the internal node 327 is pre-charged.

In the next gate selection period T3, the clock signal line 301 is switched to the low potential (VSS), and the clock signal line 302 is switched to the high potential (VDD). Thus, the gate line 321 is connected to the low potential wire 303 via the TFT 315 and discharged with the low potential (VSS). At this time, since the gate line 331 is discharged with the high potential (VDD), the TFT 313 is turned on, and the internal node 317 is connected to the low potential wire 303 and discharged with the low potential (VSS). Thus, the operation of the gate line 321 is completed. Thereafter, in accordance with the operation of the clock signal line 302, the low potential (VSS) is input into the gate line 321 via the TFT 315 and the low state is maintained until the scanning is again performed in the next frame.

As described above, the scanning drive circuit for one stage is formed of four TFTs and one capacitance, so that the scanning signal drive circuit 205 can supply the scanning signal to the gate wire 3.

The drive-circuit TFTs 211 are used as the TFTs 312, 313, 314, 315, and the like. At this time, when the TFT in the normally-on state is used as the drive-circuit TFT 211, for example, in order to keep the gate lines 311, 321, 331 in the low state, it is necessary to keep writing the low potential from the TFTs 315, 325, 335. This leads to an increase in power consumption. On the other hand, when the TFT in the normally-off state is used as the drive-circuit TFT 211, it is not necessary to keep writing the low potential from the TFTs 315, 325, 335. Therefore, when the off-leakage current of the drive-circuit TFT 211 is small, the TFTs 315, 325, 335 can be omitted to achieve further space saving and, eventually, narrowing of the LCD frame. Furthermore, when the rise of the gate voltage is 0 V or more, the low potential (VSS) can be set to 0 V. In that case, since the ground voltage (=0 V) can be used as the off voltage, the configuration that generates the off voltage becomes unnecessary, the circuit configuration can be simplified, and the circuit load can be reduced.

Therefore, in the present preferred embodiment, the back-channel type TFT is used for the pixel TFT 201, whereas the etch-stopper type TFT is used for the drive-circuit TFT 211. Returning to FIG. 4, the cross-sectional configuration of the drive-circuit TFT 211 will be described. As illustrated in FIG. 4, the TFT substrate 200 includes, for example, the substrate 1 which is a transparent insulating substrate such as glass or plastic, and a gate electrode (second gate electrode) 21 which is formed of the same conductive film and selectively disposed on the substrate 1.

The gate electrode 21 is formed of a single layer film or multilayer film using, for example, aluminum (Al), chromium (Cr), copper (Cu), molybdenum (Mo), or an alloy in which another element is added in a small amount to these.

And the insulating film 22 which covers these is disposed. Since the insulating film 22 functions as a gate insulating film, the insulating film 22 may be referred to as a gate insulating film (second gate insulating film) 22. The gate insulating film 22 is formed of a laminated film of a silicon nitride film and a silicon oxide film disposed thereon.

In the placement area of the drive-circuit TFT 211, the semiconductor layer (second oxide semiconductor layer) 25 facing the gate electrode 21 via the gate insulating film 22 is provided. Here, the semiconductor layer 25 is disposed on the gate insulating film 22 so as to overlap the gate electrode 21 in a plan view and is configured to be held within above the gate electrode 21.

The semiconductor layer 25 is made of an oxide semiconductor, and it is possible to use an oxide semiconductor containing at least indium (In) or zinc (Zn), such as zinc oxide (ZnO), indium oxide (In₂O₃), or an In—Zn—O-based oxide semiconductor mixed with ZnO. In addition to indium and zinc, other metals may be added. The other metals include Al (aluminum), Ti (titanium), Ga (gallium), Ge (germanium), Y (yttrium), Zr (zirconium), Si (silicon), Sn (tin), La (lanthanum), Ce (cerium), and Hf (hafnium), and one or more of these metals may be added. For example, the semiconductor layer 25 may be formed of an In—Ga—Zn—O-based oxide semiconductor in which Ga is added to the In—Zn—O-based oxide semiconductor.

The conductivity of the oxide semiconductor layer (semiconductor layer 25) of the present preferred embodiment is, for example, 1×10⁻⁷ to 10 S/cm. The carrier density of the oxide semiconductor layer is, for example, in the range of 1×10¹¹ to 1×10¹⁸/cm³. When the conductivity is higher than 10 S/cm, or when the carrier density is higher than 1×10¹⁸/cm³, electricity may easily flow at all times, and the semiconductor layer may not exhibit a switching function. It is more preferable that at the time of device preparation, the conductivity of the oxide semiconductor layer be, for example, in the range of 1×10⁻⁴ to 10⁻¹ S/cm, or the carrier density be in the range of 1×10¹¹ to 1×10¹⁴/cm³.

The carrier density range of the semiconductor layer 25 is low as compared to that of the semiconductor layer 12 in the pixel TFT 201 described above. This is because in the pixel TFT 201 which is a back-channel type TFT, the process damage is caused to the channel part 13 when the source electrode 7 and the drain electrode 8 are formed, and hence the carrier density easily increases as compared to the drive-circuit TFT 211 which is an etch-stopper type TFT. In addition, a silicon oxide (SiO) film is used for the etch stopper layer 20 described later, and when heat is applied during the process after the formation of the etch stopper layer 20, the etch stopper layer 20 has an oxidizing action on a semiconductor layer 25 which is an oxide semiconductor. Therefore, in the present preferred embodiment, the metal composition of the semiconductor layer 25 and the metal composition of the semiconductor layer 12 are the same as each other, but the oxygen concentration (oxygen ratio) of the semiconductor layer 25 in the drive-circuit TFT 211 is high as compared to the oxygen concentration (oxygen ratio) of the semiconductor layer 12 in the pixel TFT 201 described above. As a result, strictly speaking, the composition of the semiconductor layer 25 and the composition of the semiconductor layer 12 are different from each other.

From the above, by forming the etch-stopper type TFT, an oxide semiconductor layer having a low carrier density as compared to that of the back-channel type TFT can be prepared stably. By using such an oxide semiconductor layer with a low carrier density as a channel layer, a TFT in a normally-off state can be stably prepared as the drive-circuit TFT 211. In addition, a TFT having higher mobility than amorphous silicon can be achieved, and the operation speed can be improved.

An etch stopper layer (second insulating film) 20 is disposed on the surface of the semiconductor layer 25. On the surfaces of the etch stopper layer 20 and the semiconductor layer 25, the source electrode (second source electrode) 23 and the drain electrode (second drain electrode) 24 which are made of a conductive film and are separated from each other are disposed. Thus, each of the source electrode 23 and the drain electrode 24 is connected to the semiconductor layer 25. At the time of operation of the drive-circuit TFT 211, a channel part 26 of about the width of the etch stopper layer 20 is formed in the semiconductor layer 25 between the source electrode 23 and the drain electrode 24.

A protective insulating film (third insulating film) 27 is disposed on the source electrode 23 and the drain electrode 24 of the drive-circuit TFT 211, and the source electrode 23 and the drain electrode 24 are covered with a protective insulating film 27. The protective insulating film 27 also covers the gate insulating film 22. In the present preferred embodiment, the protective insulating film 27 is made of the same insulating film as the protective insulating film 14 and is the same layer as the protective insulating film 14. The protective insulating film 27 may be continuous with or separated from the protective insulating film 14.

As described above, the shift register 212 as illustrated in FIG. 5 is configured by combining the drive-circuit TFT 211, the clock signal lines 301, 302, the low potential wire 303, and the gate lines 311, 321, 331, 341. The drive-circuit TFT 211 constitutes a scanning signal drive circuit 205 which is a drive circuit for driving the pixel TFT 201.

<Manufacturing Method>

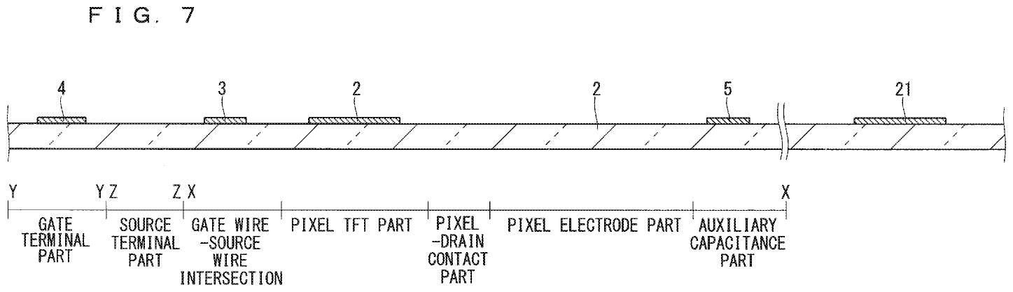

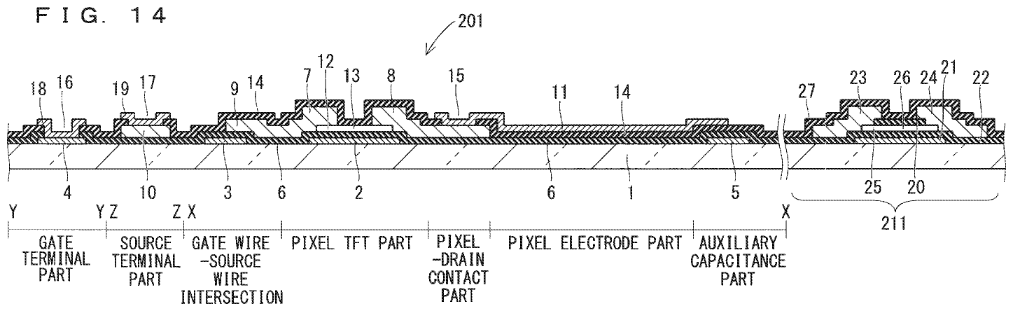

Next, a method for manufacturing the TFT substrate 200 of the present preferred embodiment will be described with reference to FIGS. 7 to 14 which are cross-sectional views sequentially illustrating the manufacturing steps. FIGS. 7 to 14 are cross-sectional views similar to the cross-sectional view illustrated in FIG. 4, and FIG. 14 is a cross-sectional view illustrating the final step and is the same as the cross-sectional view of FIG. 4.

First, the substrate 1, which is a transparent insulating substrate such as glass, is cleaned using a cleaning solution or pure water. In the present preferred embodiment, a non-alkali glass substrate having a thickness of 0.5 mm is used as the substrate 1.

Then, a first conductive film (not illustrated) is formed on the cleaned substrate 1 and patterned to form the gate electrode 2, the gate wire 3, the gate terminal 4, the auxiliary capacitance electrode 5 (including the auxiliary capacitance wire 210), and the gate electrode 21 on the substrate 1, as illustrated in FIG. 7.

Here, as the first conductive film, it is possible to use, for example, Al, Cr, Cu, Mo, and alloys in which other elements are added in a small amount to these. In addition, a laminated film in which two or more layers of these metals and alloys are formed may be used as the first conductive film. By using these metals and alloys, it is possible to obtain a low resistance film having a specific resistance value of 50 μΩcm or less (a conductivity of 2×10⁴ S/cm or more).

In the present preferred embodiment, it is assumed that a Mo film is used as the first conductive film, and a Mo film with a thickness of 200 nm is formed on the substrate by known sputtering using Ar gas. Thereafter, a resist material is applied onto the Mo film, and the resist material is exposed to light using a photomask. Next, the exposed resist material is developed, and the resist material is patterned to obtain a photoresist pattern. Hereinafter, a series of steps for forming the photoresist pattern will be referred to as a photolithography process.

The Mo film is selectively etched and patterned using the photoresist pattern (not illustrated) obtained in the photolithography process as an etching mask. Thereafter, by removing the photoresist pattern, as illustrated in FIG. 7, the gate electrode 2, the gate wire 3, the gate terminal 4, the auxiliary capacitance electrode 5 (including the auxiliary capacitance wire 210), and the gate electrode 21 are formed on the substrate 1.

In this etching process, it is possible to use known wet etching with a solution containing phosphoric acid, nitric acid and acetic acid (hereinafter referred to as “PAN solution”). As the PAN solution, one having a range of 40 to 93 wt % (weight %) of phosphoric acid, 1 to 40 wt % of acetic acid, and 0.5 to 15 wt % of nitric acid is preferred. In the present preferred embodiment, the Mo film is etched using a PAN solution containing 70 wt % of phosphoric acid, 7 wt % of acetic acid, 5 wt % of nitric acid and water, with the solution temperature set to 25° C.

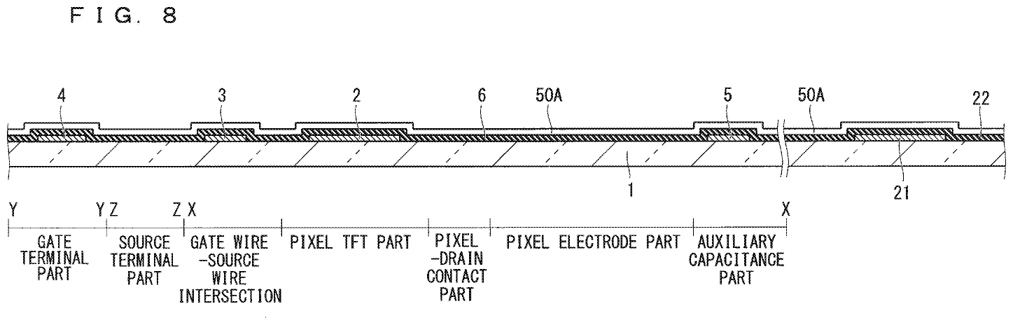

Next, in the step illustrated in FIG. 8, the gate insulating film 6 and the gate insulating film 22 are formed on and above the substrate 1, and the gate electrode 2, the gate wire 3, the gate terminal 4, and the auxiliary capacitance electrode 5 (including the auxiliary capacitance wire 210) are covered with the gate insulating film 6, while the gate electrode 21 is covered with the gate insulating film 22. For the gate insulating film 6 and the gate insulating film 22, for example, a silicon oxide (SiO) film formed using a chemical vapor deposition (CVD) is used. Here, an SiO film with a thickness of 300 nm is formed under a substrate heating condition of 150 to 400° C. by using silane (SiH₄) gas and dinitrogen monoxide (N₂O) gas.

However, the gate insulating film 6 and the gate insulating film 22 are not limited to this. For example, a SiO film has a weak barrier property (blocking property) to an impurity element that affects TFT characteristics, such as water (H₂O), hydrogen (H₂), sodium (Na), potassium (K). Therefore, a laminated film, in which a silicon nitride (SIN) film or the like excellent in barrier property is provided under the SiO film, may be used as the gate insulating film 6 and the gate insulating film 22. The SiN film can be formed by, for example, CVD using SiH₄ gas, ammonia (NH₃) gas, and nitrogen (N₂) gas. In this case, the thickness of each of the SiO film and the SiN film may be adjusted so that the thickness of the laminated film of these films is, for example, 100 to 500 nm.

Next, on the gate insulating film 6 and the gate insulating film 22, one oxide semiconductor film (semiconductor film) 50A is formed as a material for the semiconductor layer 12 and the semiconductor layer 25. The oxide semiconductor film 50A is formed by physical vapor deposition such as sputtering, vapor deposition, and ion plating. Each of these methods is generally a method in which a target material placed in a film formation chamber (reaction chamber) is irradiated with plasma or arc discharge, and a material which has jumped out of the target material due to the impact is deposited on a substrate. In this case, a gas (e.g., argon gas, etc.) necessary for discharge is introduced into the film formation chamber in addition to the target material. Further, a gas (e.g., oxygen, nitrogen, etc.) for changing the composition of a film to be deposited on the substrate or the like can also be introduced.

As thus described, according to physical vapor deposition such as sputtering, vapor deposition, and ion plating, thin films having various characteristics are formed by the combination of the target material installed in the deposition chamber and the introduced gas.

An example of a method for forming the oxide semiconductor film 50A will be described in more detail. After the substrate 1 has been disposed in the film formation chamber (reaction chamber), the pressure in the film formation chamber is reduced. Thereafter, the oxide semiconductor film 50A is formed by physical vapor deposition using a metal oxide as a target material in a film formation chamber. As the target material, for example, an InGaZnO target [In₂O₃. Ga₂O₃.(ZnO)₂] having an atomic composition ratio of In:Ga:Zn:O of 1:1:1:4 is used, and as the physical vapor deposition, for example, sputtering is used.

When the oxide target is sputtered by known sputtering using Ar gas or Kr gas, in an example where the atomic composition ratio of oxygen is smaller than the stoichiometric composition and oxygen ions are depleted [In₂O₃.Ga₂O₃.(ZnO)₂], the oxide semiconductor film 50A having a composition ratio of O of less than 4 is formed. Hence it is desirable to perform sputtering with oxygen gas (O₂) mixed with Ar gas. In the present preferred embodiment, the sputtering is performed using mixed gas, obtained by adding O₂ gas with a partial pressure ratio of 10% to Ar gas, to form the oxide semiconductor film 50A with a thickness of 40 nm.

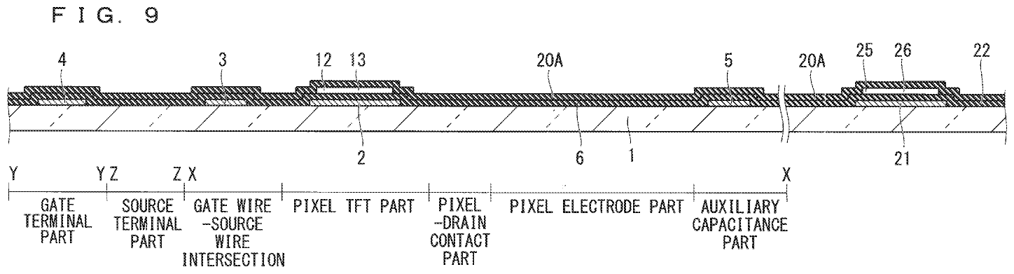

After the formation of the oxide semiconductor film 50A on the gate insulating film 6 and the gate insulating film 22, a resist material is applied onto the oxide semiconductor film 50A, a photoresist pattern (not shown) is formed in a photolithography process, and by using the photoresist pattern as an etching mask, the oxide semiconductor film 50A is selectively etched and patterned. Thereafter, by removing the photoresist pattern, as illustrated in FIG. 9, the first semiconductor film to be the semiconductor layer 12 and the second semiconductor film to be the semiconductor layer 25 are formed respectively above the gate electrode 2 and the gate electrode 21 of the pixel TFT part.

Thus, the first semiconductor film and the second semiconductor film are formed from one oxide semiconductor film 50A. The compositions of the first semiconductor film and the second semiconductor film at this point are different from the compositions of the semiconductor layer 12 and the semiconductor layer 25 of FIGS. 4 and 14 which are completed through the steps described below. For example, although the composition of the first semiconductor film and the composition of the second semiconductor film at this point are substantially the same, the compositions of the semiconductor layer 12 and the composition of the semiconductor layer 25 in FIGS. 4 and 14 are different from each other. However, for convenience of description, the first semiconductor film and the second semiconductor film formed from one oxide semiconductor film 50A will be respectively described below with the same reference numerals as the semiconductor layer 12 and the semiconductor layer 25.

In the etching process of the oxide semiconductor film 50A, known wet etching with a solution containing carboxylic acid can be used. As the solution containing carboxylic acid, one containing oxalic acid in the range of 1 to 10 wt % is preferred. In the present preferred embodiment, the semiconductor layer 12 and the semiconductor layer 25 are formed using an oxalic acid-based solution containing 5 wt % of oxalic acid and water with setting the liquid temperature of the solution to 25° C.

The edges of the semiconductor layer 12 and the semiconductor layer 25 do not protrude outside the edges of the gate electrode 2 and the gate electrode 21 in the plan view, respectively, as illustrated in FIG. 3. That is, the semiconductor layer 12 and the semiconductor layer 25 are formed such that the whole of the semiconductor layer 12 and the semiconductor layer 25 are held inside the edges of the gate electrode 2 and the gate electrode 21, respectively. Thus, in the transmissive LCD that performs display by selectively transmitting light emitted from the backlight unit to the back surface of the TFT substrate 1004 in FIG. 1, the patterns of the gate electrode 2 and the gate electrode 21 serve as a light shielding mask to prevent the direct incidence of the light on the semiconductor layer 12 and the semiconductor layer 25. This can result in preventing the deterioration of the TFT characteristics due to light irradiation.

After the etching process has been performed, annealing is performed at 350° C. in the air for one hour. By performing the annealing, etching damage to the semiconductor layer 12 and the semiconductor layer 25 in the etching process of the next step can be reduced.

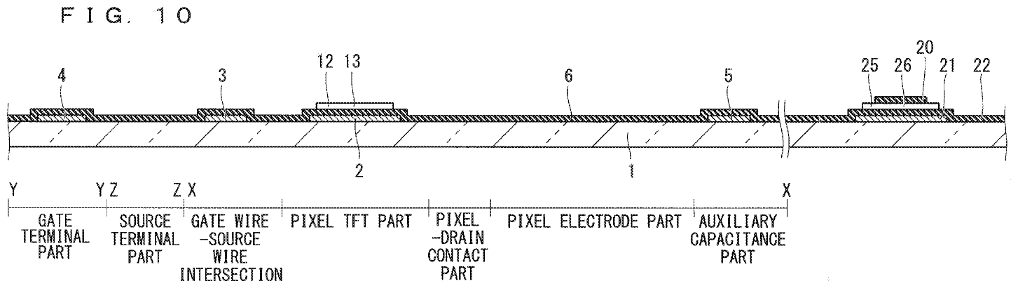

Thereafter, as illustrated in FIG. 9, an insulating film (fourth insulating film) 20A to be a material for the etch stopper layer 20 is formed on the surfaces of the gate insulating film 6, the gate insulating film 22, the semiconductor layer 12, and the semiconductor layer 25. Then, as illustrated in FIG. 10, patterning is performed to remove the portion of the insulating film 20A other than the portion on the surface of the semiconductor layer 25, thereby forming the portion as the etch stopper layer 20. That is, although the etch stopper layer 20 is formed in the drive-circuit TFT 211, the insulating film 20A is entirely removed in the pixel TFT 201. On the semiconductor layer 25, the etching stopper layer 20 may only be provided covering at least the channel part 26 on the semiconductor layer 25, and a portion of the etch stopper layer 20 where the semiconductor layer 25 is exposed may only be provided on both sides of the channel part 26. In addition, in the pixel TFT 201 where the etch stopper layer 20 is not provided, due to the need for the removal of the insulating film 20A, patterning may be performed so as to leave the portion on the surface of the semiconductor layer 25 in the insulating film 20A as the etch stopper layer 20 and remove the placement area of the pixel TFT 201, that is, the insulating film 20A on the surface of the semiconductor layer 12, while leaving the insulating film 20A in the other areas is left

For the etch stopper layer 20, a silicon oxide (SiO) film formed by using, for example, CVD is used. Here, using silane (SiH₄) gas and dinitrogen monoxide (N₂O) gas, an SiO film with a thickness of 300 nm is formed as the etch stopper layer 20 under a substrate heating condition of 150 to 400° C.

The SiO film has a weak barrier property (blocking property) to impurity elements that affect TFT characteristics, such as water (H₂O), hydrogen (H₂), sodium (Na), and potassium (K), but the whole SiO film is covered with the protective insulating film 14 and the protective insulating film 27 after the formation of the source electrode 7, the source electrode 23, the drain electrode 8, and the drain electrode 24, and hence there is no problem even if a single SiO film is used for the etch stopper layer 20. However, in order to prevent hydrogen radicals and the like during the formation of the SiO film from reducing the oxide semiconductors of the semiconductor layers 12, 25, it is desirable to set the film formation rate to be low by reducing the silane flow rate as much as possible at the time of forming the SiO film as the etch stopper layer 20.

Further, annealing may be performed after the patterning of the etch stopper layer 20. By heating between 150 and 400° C., an oxidation component in the etch stopper layer 20 acts on the semiconductor layer 25 to oxidize the semiconductor layer 25, thereby having an effect of lowering the concentration of the carrier density of the semiconductor layer 25 more than the carrier density of the semiconductor layer 12. In general, a TFT having a semiconductor layer with a low carrier density is likely to come into the normally-off state.

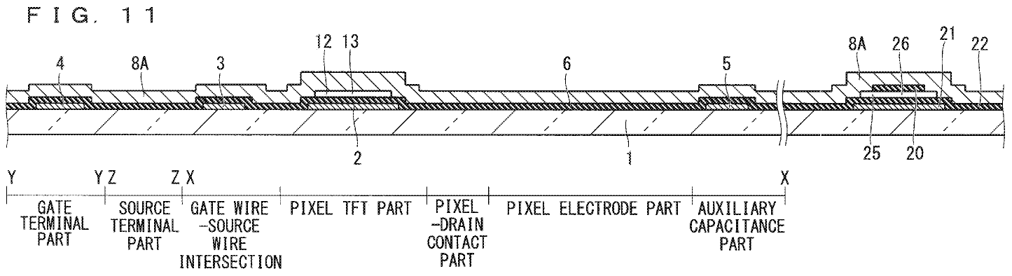

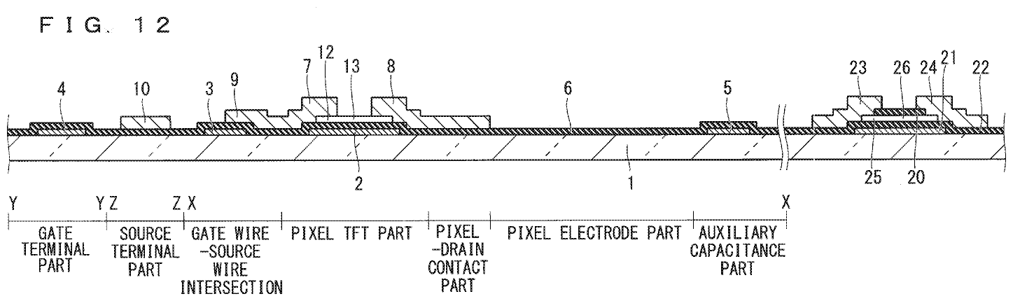

Next, in a step illustrated in FIG. 11, a conductive film 8A (second conductive film) is formed above the substrate 1 and patterned to form the source electrode 7, the source electrode 23, the drain electrode 8, the drain electrode 24, the source wire 9, and the source terminal 10, as illustrated in FIG. 12. At this time, a gap is formed on the channel part 13 and the channel part 26 of the semiconductor layer 12 and the semiconductor layer 25.

Here, as the conductive film 8A, it is possible to use, for example, Al, Cr, Cu, Mo, and alloys in which other elements are added in a small amount to these. In addition, a laminated film in which two or more layers of these metals and alloys are formed may be used as the conductive film 8A. By using these metals and alloys, it is possible to obtain a low resistance film having a specific resistance value of 50 μΩcm or less (a conductivity of 2×10⁴ S/cm or more).

In the present preferred embodiment, a Mo film is used as the conductive film 8A, and the Mo film is formed to have a thickness of 200 nm by known sputtering using the Ar gas. Thereafter, a resist material is applied onto the Mo film, a photoresist pattern (not illustrated) is formed in a photolithography process, and the Mo film is selectively etched and patterned using the photoresist pattern as an etching mask.

In this etching process, known wet etching with the PAN solution can be used. In the present preferred embodiment, the Mo film is etched using a PAN solution containing 70 wt % of phosphoric acid, 7 wt % of acetic acid, 5 wt % of nitric acid and water, with the solution temperature set to 25° C.

Thereafter, the photoresist pattern is removed to form the source electrode 7 and the drain electrode 8 electrically connected to the semiconductor layer 12, the source electrode 23 and the drain electrode 24 electrically connected to the semiconductor layer 25, the source wire 9, and the source terminal 10, as illustrated in FIG. 12.

Further, annealing may be performed after the patterning of the source electrodes 7, 23, the drain electrodes 8, 24, the source wire 9, and the source terminal 10. For example, by heating between 150 and 400° C., a process may be performed in which the oxidation component in the etch stopper layer 20 oxidizes the semiconductor layer 25. That is, the semiconductor layer 25 may be formed by performing a process of oxidizing the second semiconductor film formed of one oxide semiconductor film 50A. This has the effect of lowering the carrier density of the semiconductor layer 25 more than the carrier density of the semiconductor layer 12. In general, a TFT having a semiconductor layer with a low carrier density is likely to come into the normally-off state, and hence the drive-circuit TFT 211 is in the normally-off state.

Further, in the pixel TFT 201 where the etch stopper layer does not exist, the threshold value of the TFT changes due to the heating of the annealing process. In a general annealing furnace, moisture easily intrudes into the furnace when the furnace is opened and closed, and a small amount of water vapor acts on the channel part 13 of the pixel TFT 201 to shift the threshold to the negative side, so that the pixel TFT 201 comes into the normally-on state.

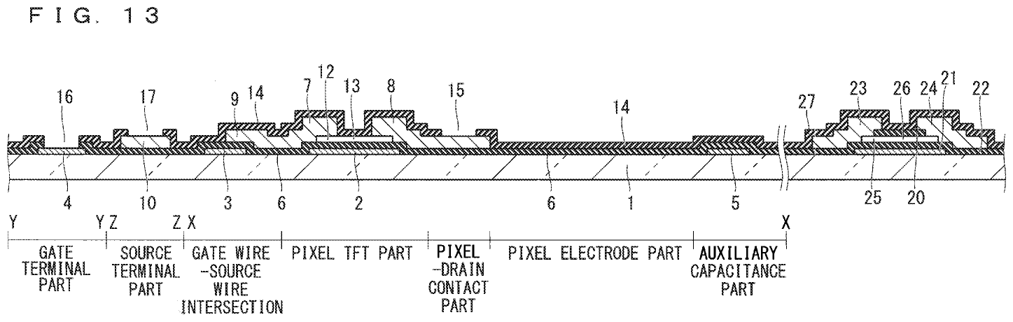

Next, in the process illustrated in FIG. 13, the protective insulating film 14 is formed so as to cover the source electrode 7, the drain electrode 8, the source wire 9, the source terminal 10, and the channel part 13. The protective insulating film 27 is formed so as to cover the source electrode 23, the drain electrode 24, and the etch stopper layer 20 on the channel part 26. Thereafter, the pixel drain contact hole 15 which penetrates the protective insulating film 14 to reach the drain electrode 8, the source-terminal contact hole 17 which penetrates the protective insulating film 14 to reach the source terminal 10, and the gate-terminal contact hole 16 which penetrates the protective insulating film 14 and the gate insulating film 6 to reach the gate terminal 4 are formed. Although not illustrated, contact holes similar to these are also formed in the protective insulating film 27 and the gate insulating film 22.

In the present preferred embodiment, for the protective insulating films 14, 27, for example, an SiO film with a thickness of 300 nm is formed by using CVD using silane (SiH₄) gas and dinitrogen monoxide (N₂O) gas under a condition where the substrate 1 is heated within the temperature range of 150 to 400° C. Then, a resist material is applied onto the SiO film, a photoresist pattern is formed in a photolithography process, and the silicon oxide film is selectively etched using the photoresist pattern as an etching mask to form the protective insulating films 14, 27. In this etching step, known dry etching using fluorine gas can be used.

The SiO film has a weak barrier property (blocking property) to an impurity element that affects TFT characteristics, such as water (H₂O), hydrogen (H₂), sodium (Na), potassium (K). Therefore, a laminated film, in which a silicon nitride (SiN) film or the like excellent in barrier property is provided on the SiO film, may be used as the protective insulating films 14, 27. Even in such a laminated film, the contact hole can be formed by using the known dry etching method using the fluorine gas.

Further, in the pixel TFT 201 where the etch stopper layer is not provided, in processes after the formation of the source electrodes 7, 23 and the drain electrode 8, which are processes after the patterning of the etch stopper layer 20, such as the formation process of the protective insulating film 14, the semiconductor layer 13 is in an exposed state. Therefore, depending on whether the process is an oxidizing process or a reducing process on the substrate surface, and further, depending on the degrees of these processes, the influence on the carrier density of the semiconductor layer 13 is increased. On the other hand, in the drive-circuit TFT 211 provided with the etch stopper layer, since the semiconductor layer 25 is covered with the etch stopper layer 20, there is not much influence due to the actions on the semiconductor layer 25 by these processes.

That is, with regard to the action exerted on the substrate surface in the process of forming the protective insulating film 14, by appropriately adjusting whether the process is the oxidizing process or the reducing process, and further, the degrees of those actions, the carrier density of only the semiconductor layer 13 and the threshold value of the pixel TFT 201 can be adjusted in a freely selected manner within a certain range without substantially changing the carrier density of the semiconductor layer 25 and the threshold value of the drive-circuit TFT 211. In particular, in the process of forming the protective insulating film 14, the reducing action by hydrogen from the silane (SiH₄) gas and the oxidizing action by the dinitrogen monoxide (N₂O) gas are mixed. Therefore, depending on film forming conditions including the mixing ratio of silane and dinitrogen monoxide, it is possible to finely adjust whether the process is the oxidizing process or the reducing process, and further, the degrees of those actions. Specifically, the threshold value can be shifted to the negative side by the reducing action becoming stronger or the oxidizing action becoming weaker, and on the contrary, the threshold value can be shifted to the positive side by the reducing action becoming weaker or the oxidizing action becoming stronger.

Further, as described above, when a laminated film in which a silicon nitride (SiN) film is provided on an SiO film is used as the protective insulating films 14, 27, the silicon nitride (SiN) film is generally formed using silane (SiH₄) gas and ammonia (NH₃) gas by using CVD, and a process in which the reducing action with hydrogen supplied from both silane (SiH₄) gas and ammonia (NH₃) gas is relatively strong is performed. However, in the drive-circuit TFT 211 provided with the etch stopper layer, the semiconductor layer 25 is in the state of being covered with the SiO film constituting the etch stopper layer 20 and the protective insulating film 27, and the drive-circuit TFT 211 is hardly affected by the reducing action due to the process of forming this silicon nitride (SiN) film. On the other hand, the pixel TFT 201 having no etch stopper layer is affected by the reducing action on the semiconductor layer 13 as compared to the drive-circuit TFT 211, although the drive-circuit TFT 211 is in the state of being covered with the SiO film constituting the protective insulating film 14. Further, with respect to hydrogen supplied at the time of formation of the silicon nitride (SiN) film, a difference occurs between the SiO films constituting the etch stopper layer 20 and the protective insulating film 14, and the hydrogen concentration of the etch stopper layer 20 is low as compared to the hydrogen concentration of the SiO film constituting the protective insulating film 14. That is, according to the configuration using the laminated film in which the silicon nitride (SiN) film is provided on the SiO film as the protective insulating films 14, 27 accompanied with the formation process of the silicon nitride (SiN) film having the reducing action, a difference occurs between the carrier density of the semiconductor layer 12 and the carrier density of the semiconductor layer 25. This thus contributes to obtaining the desired configuration in the present preferred embodiment, that is, the configuration of the pixel TFT 201 and the drive-circuit TFT 211 having the feature in which the carrier density of the semiconductor layer 12 is higher than the carrier density of the semiconductor layer 25.

Next, in a step illustrated in FIG. 14, a conductive film (third conductive film) is formed on the substrate 1 to embed the pixel drain contact hole 15, the gate-terminal contact hole 16, and the source-terminal contact hole 17.

A transparent conductive film is formed as the conductive film. As the transparent conductive film, in the present preferred embodiment, an InZnO film (a mixing ratio of indium oxide (In₂O₃) to zinc oxide (ZnO) in weight % of 90:10), which is a known conductive oxide, is used. Here, an InZnO film with a thickness of 100 nm was formed using the known sputtering. However, the transparent conductive film is not limited to an indium zinc oxide (IZO) film such as an InZnO film as described above, and an indium tin oxide (ITO) film or the like can also be used.

Thereafter, a resist material is applied onto the conductive film, a photoresist pattern (not illustrated) is formed in a photolithography process, and the conductive film is selectively etched and patterned using the photoresist pattern as an etching mask. Thereafter, by removing the photoresist pattern, as illustrated in FIGS. 4 and 14, the transmissive pixel electrode 11, the gate terminal pad 18, and the source terminal pad 19 are formed, and the TFT substrate 200 is completed.

For the etching process of the InZnO film, known wet etching with an oxalic acid solution can be used.

In the present preferred embodiment, the reason for using a transparent conductive film as the conductive film is that it is necessary to form a translucent pixel electrode in a transmissive LCD that selectively transmits light from the backlight unit to perform display. On the other hand, in the case of forming a reflective LCD that selectively reflects external light to perform display, metal films such as Al and silver (Ag) that reflect light may be formed as pixel electrodes. Further, in the case of forming a semi-transmissive LCD having both reflection and transmission, a pixel electrode having both characteristics of light reflectivity and transmittance may be formed.

An alignment film and a spacer (not illustrated) are formed on the surface of the completed TFT substrate 200 (corresponding to the TFT substrate 1004 in FIG. 1). The alignment film is a film for arranging liquid crystal molecules and is made of polyimide or the like. Further, the counter substrate 1006 (FIG. 1) provided with a color filter and an alignment film is prepared, and the TFT substrate 1004 and the counter substrate 1006 are bonded to each other. Then, a liquid crystal is injected and held in a gap formed between the two substrates by the above spacer to form the liquid crystal layer 1005. Thereafter, polarizing plates 1003, 1007 are disposed outside the two substrates, a backlight unit is disposed further outside the TFT substrate 1004, and a retardation plate is disposed further outside the counter substrate 1006. Thus, the liquid crystal display 1000 of FIG. 1 can be formed.

### Example of Preferred Embodiment

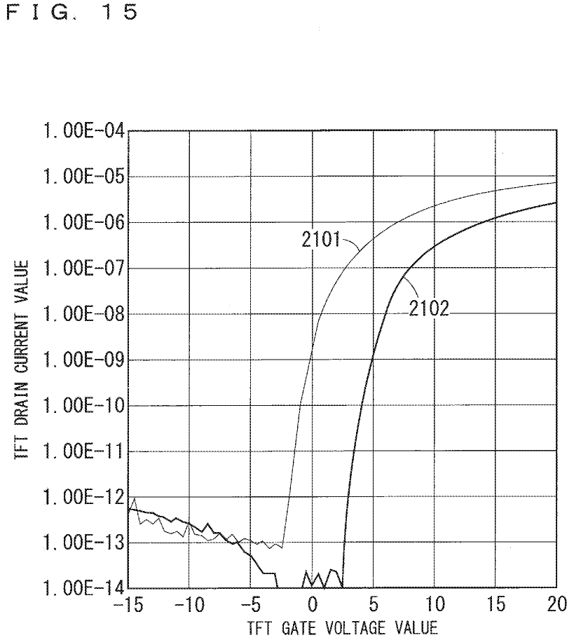

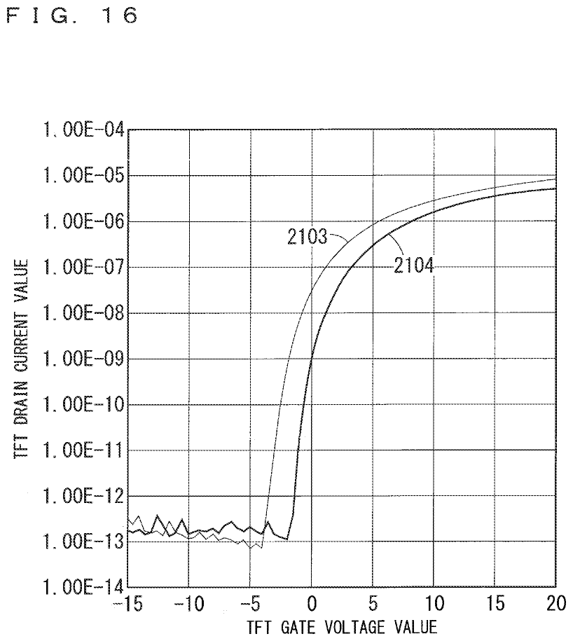

The TFT substrate according to an example was experimentally produced using the manufacturing method according to the above preferred embodiment. FIG. 15 illustrates the drain current-gate voltage dependency of the pixel TFT and the drive-circuit TFT in the TFT substrate according to the example. Further, as a comparative example, FIG. 16 illustrates the drain current-gate voltage dependency of the pixel TFT and the drive-circuit TFT in the TFT substrate experimentally produced by the method of Patent Document 1.

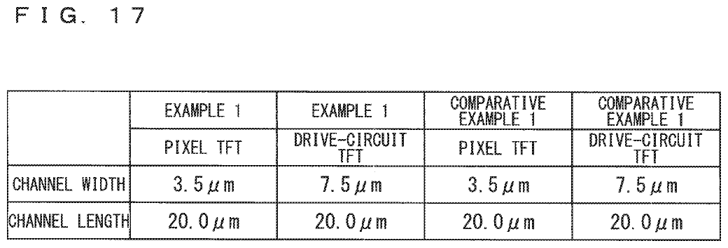

The pixel TFT in the TFT substrate in the example is a back-channel type TFT, and the drive-circuit TFT is an etch-stopper type TFT. The length corresponding to the channel between the source electrode and the drain electrode is defined as the channel width, and the shorter one of the length of the source/drain electrode and the length of the semiconductor layer in the direction perpendicular to the channel width is defined as the channel length. FIG. 17 illustrates channel widths and channel lengths of the example and the comparative example.

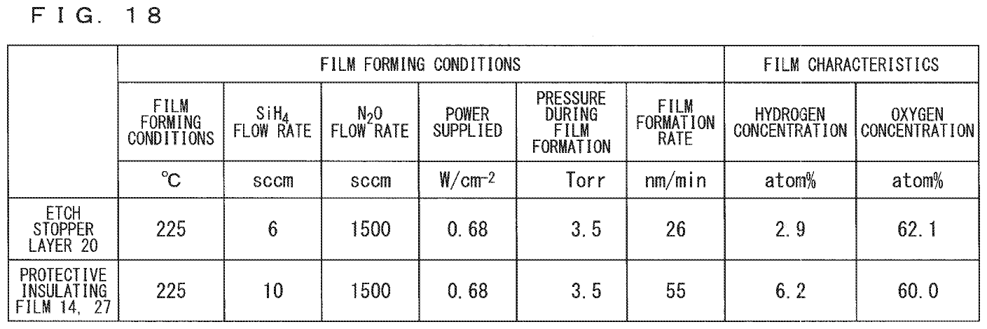

Further, FIG. 18 illustrates the film forming conditions and film characteristics of the etch stopper layer 20 and the protective insulating films 14, 27 in the example and the comparative example. In order to prevent hydrogen radicals and the like during the formation of the SiO film from reducing the oxide semiconductor which is a material for the semiconductor layers 12, 25, at the time of forming the SiO film as the etch stopper layer 20, it is desirable to set the film formation rate to be low by reducing the silane flow rate as much as possible. Reflecting this, as illustrated in FIG. 18, the flow rate of silane at the time of film formation of the etch stopper layer 20 is lower than the flow rate of silane at the time of film formation of the protective insulating films 14, 27. As a result, the hydrogen concentration of the etch stopper layer 20 is low as compared to the hydrogen concentration of the protective insulating films 14, 27, and the oxygen concentration of the etch stopper layer 20 is high as compared to the oxygen concentration of the protective insulating films 14, 27.

Meanwhile, regarding dinitrogen monoxide (N₂O) gas, as described above, the oxidizing action can be obtained. Therefore, here, an example is shown where the flow rate of dinitrogen monoxide at the time of film formation of the etch stopper layer 20 and the flow rate of dinitrogen monoxide at the time of film formation of the protective insulating films 14, 27 are the same, but, for example, the flow rate of dinitrogen monoxide at the time of forming the etch stopper layer 20 may be higher than the flow rate of dinitrogen monoxide at the time of forming the protective insulating films 14, 27. Thereby, the action is exerted so as to make the hydrogen concentration of the etch stopper layer 20 low as compared to the hydrogen concentration of the protective insulating films 14, 27, and make the oxygen concentration of the etch stopper layer 20 high as compared to the oxygen concentration of the protective insulating films 14, 27. By providing a difference in the flow rate of dinitrogen monoxide as thus described, a difference in hydrogen concentration or a difference in oxygen concentration may be provided in the etch stopper layer 20 and the protective insulating films 14, 27.

The hydrogen concentration in the SiO film was measured using elastic recoil detection analysis (ERDA). The oxygen concentration and the Si concentration in the SiO film were measured using X-ray photoelectron spectroscopy (XPS).

As illustrated in FIG. 15, the threshold voltage is significantly different between a drain current-gate voltage dependency 2101 of the pixel TFT and the drain current-gate voltage dependency 2102 of the drive-circuit TFT in the example For convenience, it is assumed that the threshold voltage of drain current-gate voltage dependency is a voltage value at which the TFT drain current value is 10⁻¹⁰ A (ampere). The threshold voltage is generally an on/off boundary voltage in the TFT. Further, the threshold voltage of the pixel TFT in the example shows a negative value as indicated by the drain current-gate voltage dependency 2101 of the pixel TFT, whereas the threshold voltage of the drive-circuit TFT shows a positive value as indicated by the drain current-gate voltage dependency 2102 of the drive-circuit TFT.

In contrast, as illustrated in FIG. 16, a difference between the threshold voltage of a drain current-gate voltage dependency 2103 of the pixel TFT and the threshold voltage of the drain current-gate voltage dependency 2104 of the drive-circuit TFT in the comparative example is small as compared to the example. Further, the threshold voltages of the pixel TFT of the comparative example and the drive-circuit TFT both are negative values. That is, in the comparative example, a process margin is small and it is difficult to differently make Vth positive and negative.

### Gist of Preferred Embodiment

As described above, the thin-film transistor substrate according to the present preferred embodiment is provided with: a first thin-film transistor and a second thin-film transistor disposed on a substrate. The first thin-film transistor includes a first gate electrode disposed on the substrate, a first gate insulating film covering the first gate electrode, a first oxide semiconductor layer facing the first gate electrode via the first gate insulating film, a first source electrode and first drain electrode that are disposed on a surface of the first oxide semiconductor layer and separated from each other, and a first insulating film disposed on the first oxide semiconductor layer, the first source electrode, and the first drain electrode. The second thin-film transistor includes a second gate electrode disposed on the substrate, a second gate insulating film covering the second gate electrode, a second oxide semiconductor layer facing the second gate electrode via the second gate insulating film, a second insulating film disposed on the second oxide semiconductor layer, and a second source electrode and a second drain electrode that are disposed on surfaces of the second insulating film and the second oxide semiconductor layer and separated from each other.

According to such a thin-film transistor substrate, it is possible to form TFTs having different threshold voltages on the same substrate with high reproducibility by a common process.

Further, the threshold voltage of the first thin-film transistor can be made negative and the threshold voltage of the second thin-film transistor can be made positive by appropriately adjusting a configuration that is disposed above the first oxide semiconductor layer and the second semiconductor layer having a correlation with the threshold voltage of the first thin-film transistor and the second thin-film transistor, the configuration affecting the carrier density and the oxygen ratio of each of the first oxide semiconductor layer and the second oxide semiconductor layer, or appropriately adjusting the manufacturing process that is performed after the formation of the first semiconductor film to be the first oxide semiconductor layer and the second semiconductor film to be the second oxide semiconductor layer from the one semiconductor film. More specifically, the threshold voltage of the first thin-film transistor can be made negative and the threshold voltage of the second thin-film transistor can be made positive by, for example, using one or more of the following steps: (1) further providing a third insulating film disposed on the second source electrode and the second drain electrode and in the same layer as the first insulating film; (2) making the hydrogen concentration and the oxygen concentration of the second insulating film and the third insulating film different from each other, and appropriately adjusting the concentrations; (3) performing a process of oxidizing the second semiconductor film with an oxidation component in the second insulating film by performing annealing after the formation of the second semiconductor film in the manufacturing process performed after the formation of the first semiconductor film and the second semiconductor film; and (4) providing at least one of an oxidizing process and a reducing process on the surface of the transistor substrate and appropriately adjusting the selection of the oxidizing process and the reducing process and the degrees of the action in a state where there is a difference in the presence or absence of the third insulating film above the first semiconductor film and the second semiconductor film.

Further, a pixel electrode connected to the first thin-film transistor is provided, the first thin-film transistor and the pixel electrode constitute a pixel part, and the second thin-film transistor constitutes a drive circuit that drives the first thin-film transistor, whereby a thin-film transistor substrate having characteristics suitable as a thin-film transistor for pixel or drive circuit can be obtained. More specifically, for the thin-film transistor for pixel, a thin-film transistor substrate having a characteristic of the normally-on state or a characteristic of the negative threshold voltage can be obtained, and for the thin-film transistor for drive circuit, a thin-film transistor substrate having a characteristic of the normally-off state or a characteristic of the positive threshold voltage can be obtained.

### First Modification

According to the manufacturing method of the preferred embodiment, the threshold voltage can be controlled. Here, in the TFT having the oxide semiconductor as the channel, a change in threshold voltage due to the manufacturing process is large as compared to the change in a TFT having amorphous silicon or polysilicon as a channel.

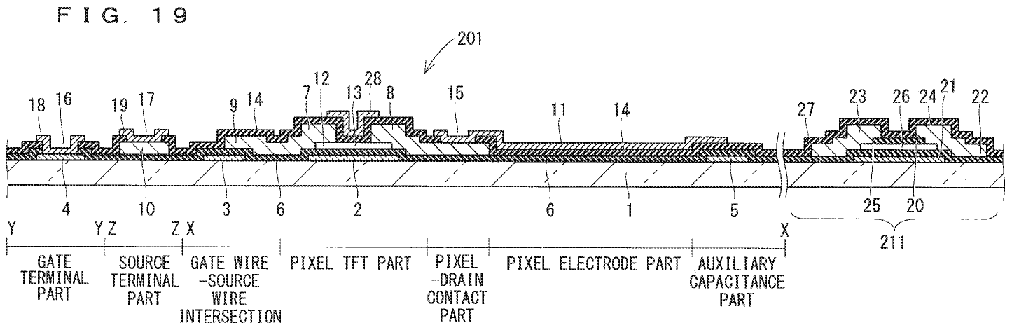

Hence the back-gate electrode 28 may be disposed using, for example, a layer of a conductive film used for forming the transmissive pixel electrode 11. FIG. 19 is a cross-sectional view illustrating a pixel TFT and a drive-circuit TFT according to the present first modification. The TFT substrate 200 of FIG. 19 is disposed with a back-gate electrode 28, which is a first back-gate electrode disposed on the protective insulating film 14 and overlapping the semiconductor layer 12 in a plan view, in addition to the configuration of FIG. 4.

The back-gate electrode 28 can be connected to the outside of the display area 202 from the top of the channel part 13 through the top of the source wire 9. Therefore, by providing a terminal (not illustrated) outside the display area 202, a voltage can always be applied from the back-gate electrode 28 to the channel part 13 located therebelow, so that the threshold voltage of the pixel TFT 201 can be controlled stably. As a result, the TFTs with different threshold voltages can be formed on the same substrate with high reproducibility by a common process.

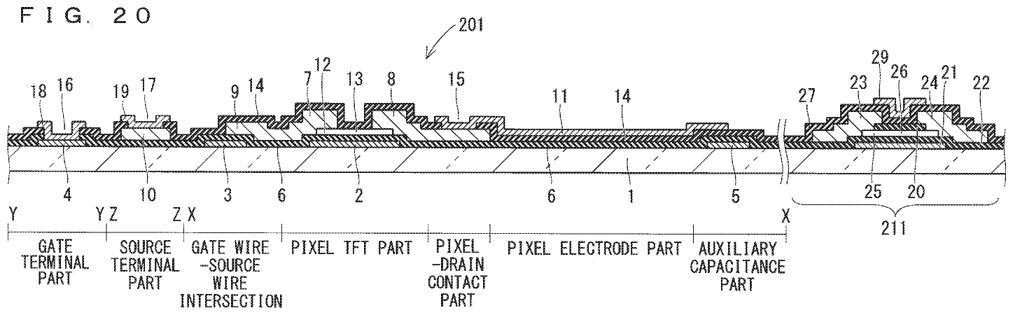

As illustrated in FIG. 20, the TFT substrate 200 may include, in place of the back-gate electrode 28, a back-gate electrode 29 that is a second back-gate electrode disposed on the protective insulating film 27 and overlapping the semiconductor layer 25 in a plan view. In this case, the threshold voltage of the drive-circuit TFT 211 can be stably controlled, and hence the TFTs with different threshold voltages can be formed on the same substrate with high reproducibility by a common process. The TFT substrate 200 may include both the back-gate electrode 28 and the back-gate electrode 29.

### Example of First Modification

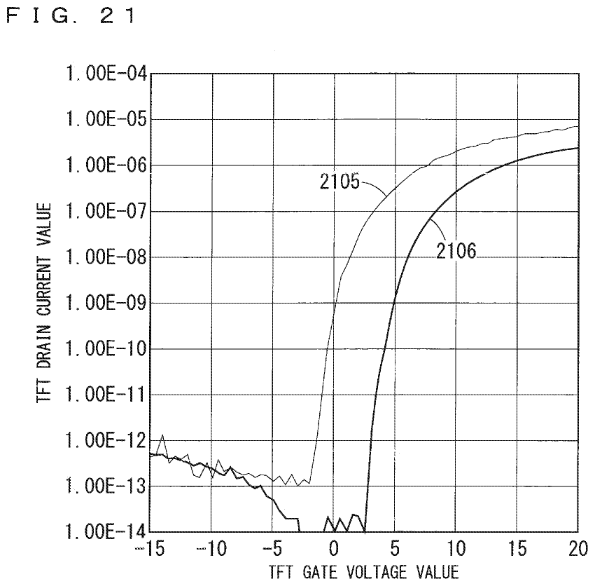

The TFT substrate according to the present first modification, that is, the TFT substrate provided with the back-gate electrode 28 was experimentally produced as an example. FIG. 21 illustrates the drain current-gate voltage dependency of the pixel TFT and the drive-circuit TFT in the TFT substrate. As in the TFT substrate according to the preferred embodiment, in the TFT substrate in the example of the present first modification, the pixel TFT is a back-channel type TFT, and the drive-circuit TFT is an etch-stopper type TFT. The channel width and the channel length of the example of the present first modification are the same as those of the example of the preferred embodiment. Further, the film forming conditions of the etch stopper layer 20 and the protective insulating films 14, 27 in the example of the present first modification are the same as those in the example of the preferred embodiment.

As illustrated in FIG. 21, the difference in threshold voltage between a drain current-gate voltage dependency 2105 of the pixel TFT and a drain current-gate voltage dependency 2106 in the example of the present first modification is small as compared to the difference of the example of the preferred embodiment (FIG. 15) but is large as compared to the difference of the comparative example (FIG. 16). Further, the threshold voltage of the pixel TFT in the example shows a negative value as indicated by the drain current-gate voltage dependency 2105 of the pixel TFT, whereas the threshold voltage of the drive-circuit TFT shows a positive value as indicated by the drain current-gate voltage dependency 2106 of the drive-circuit TFT. Further, in the example of the present first modification, as in the example of the preferred embodiment, the threshold voltage of the drain current-gate voltage dependency 2105 of the pixel TFT is a negative value near 0 V, thereby enabling achievement of a TFT with little leak current and high reliability.

### Second Modification

As described above, in the preferred embodiment, the placement area of the etch stopper layer 20 is included in the placement area of the semiconductor layer 25 in a plan view. With such a configuration, the patterning process of the etch stopper layer 20 and the semiconductor layers 12, 25 can be performed by a common mask process using, for example, a gray-tone mask.

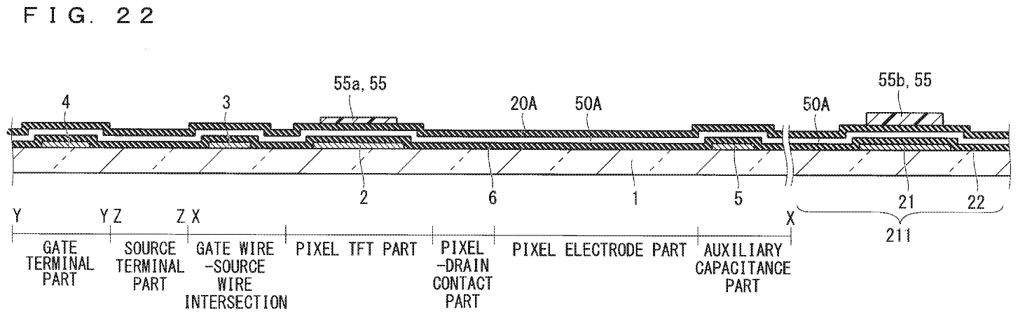

Specifically, after one oxide semiconductor film 50A has been formed by the process of FIG. 8, an insulating film 20A is formed over the oxide semiconductor film 50A as illustrated in FIG. 22. Then, a photoresist pattern 55 is formed using, for example, a gray-tone mask. Here, the photoresist pattern 55 has a thin pattern 55a which is a first portion facing the gate electrode 2 via the insulating film 20A, and a thick pattern 55b which is a second portion facing the gate electrode 21 via the insulating film 20A and being thicker than the thin pattern 55a.

Thereafter, the insulating film 20A is selectively etched using the photoresist pattern 55, and then the oxide semiconductor film 50A is selectively etched to form the semiconductor layers 12, 25 as illustrated in FIG. 10.

Then, ashing or the like is performed on the photoresist pattern 55 to remove the thin pattern 55a while thinning the thick pattern 55b. Thereafter, the insulating film 20A on the semiconductor layer 25 is left using the thinned thickness pattern 55b, while the insulating film 20A on the semiconductor layer 12 is removed, to form the etching stopper layer 20. Then, the thinned thickness pattern 55b is removed to form a configuration similar to that illustrated in FIG. 10.

According to the manufacturing method of the present second modification as described above, since the etch stopper layer 20 and the semiconductor layers 12, 25 can be patterned by one mask process, further mask saving can be achieved.

### Third Modification

The TFT substrate 200 of the preferred embodiment and each modification described above may be used for displays other than the liquid crystal display. For example, the present invention can be applied to an electro-optical display such as an organic electroluminescence (EL) display. In addition, the pixel TFT 201 may be used as a thin-film transistor used in a semiconductor device other than the electro-optical display, or the pixel TFT 201 may be used as a thin-film transistor of an active matrix substrate other than the electro-optical display.

In the present invention, within the scope of the invention, the preferred embodiment and the modifications can be appropriately modified or omitted.

While the invention has been shown and described in detail, the foregoing description is in all aspects illustrative and not restrictive. It is therefore understood that numerous modifications and variations can be devised without departing from the scope of the invention.

What is claimed is:

1. A thin-film transistor substrate comprising:
a first thin-film transistor and a second thin-film transistor disposed on a substrate,
wherein
the first thin-film transistor includes
a first gate electrode disposed on the substrate,
a first gate insulating film covering the first gate electrode,
a first oxide semiconductor layer facing the first gate electrode via the first gate insulating film,
a first source electrode and a first drain electrode that are disposed on a surface of the first oxide semiconductor layer and separated from each other, and
a first insulating film disposed on the first oxide semiconductor layer, the first source electrode, and the first drain electrode, and
the second thin-film transistor includes
a second gate electrode disposed on the substrate,
a second gate insulating film covering the second gate electrode,
a second oxide semiconductor layer facing the second gate electrode via the second gate insulating film,
a second insulating film disposed on the second oxide semiconductor layer, and
a second source electrode and a second drain electrode that are disposed on surfaces of the second insulating film and the second oxide semiconductor layer and separated from each other.

2. The thin-film transistor substrate according to claim 1, wherein the second thin-film transistor further includes a third insulating film disposed on the second source electrode and the second drain electrode and in the same layer as the first insulating film.

3. The thin-film transistor substrate according to claim 1, wherein a metal composition of the first oxide semiconductor layer and a metal composition of the second oxide semiconductor layer are the same.

4. The thin-film transistor substrate according to claim 1, wherein an oxygen ratio of the second oxide semiconductor layer is higher than an oxygen ratio of the first oxide semiconductor layer.

5. The thin-film transistor substrate according to claim 1, wherein a carrier density of the second oxide semiconductor layer is lower than a carrier density of the first oxide semiconductor layer.

6. The thin-film transistor substrate according to claim 1, wherein
a gate threshold of the first thin-film transistor is a negative threshold, and
a gate threshold of the second thin-film transistor is a positive threshold.

7. The thin-film transistor substrate according to claim 2, wherein a hydrogen concentration of the second insulating film is lower than a hydrogen concentration of the third insulating film.

8. The thin-film transistor substrate according to claim 2, wherein an oxygen concentration of the second insulating film is higher than an oxygen concentration of the third insulating film.

9. The thin-film transistor substrate according to claim 1, further comprising:
a first back-gate electrode disposed on the first insulating film and overlapping the first oxide semiconductor layer in a plan view.

10. The thin-film transistor substrate according to claim 2, further comprising:
a second back-gate electrode disposed on the third insulating film and overlapping the second oxide semiconductor layer in a plan view.

11. A method for manufacturing the thin-film transistor substrate according to claim 1, wherein a first semiconductor film to be the first oxide semiconductor layer and a second semiconductor film to be the second oxide semiconductor layer are formed from one semiconductor film.

12. The method for manufacturing the thin-film transistor substrate according to claim 11, comprising:
forming a fourth insulating film on a surface of the first semiconductor film and a surface of the second semiconductor film; and
leaving a portion of the fourth insulating film on the surface of the second semiconductor film and removing at least a portion of the fourth insulating film on the surface of the first semiconductor film to form the portion left on the surface of the second semiconductor film as the second insulating film.

13. The method for manufacturing the thin-film transistor substrate according to claim 12, wherein
the second insulating film has an oxidation component, and
after the step of forming the second insulating film, a process of oxidizing the second semiconductor film is performed by performing annealing treatment to form the second oxide semiconductor layer.

14. The method for manufacturing the thin-film transistor substrate according to claim 12, further comprising
performing at least one of an oxidizing process and a reducing process on a surface of the thin-film transistor substrate after the step of forming the second insulating film.

15. The method for manufacturing the thin-film transistor substrate according to claim 12, further comprising
performing both an oxidizing process and a reducing process on a surface of the thin-film transistor substrate after the step of forming the second insulating film.

16. The method for manufacturing the thin-film transistor substrate according to claim 13, comprising:
patterning the one semiconductor film by using a photoresist pattern having a first portion and a second portion thicker than the first portion;
removing the first portion while thinning the second portion of the photoresist pattern; and
forming the second insulating film from the fourth insulating film by using the thinned second portion.

17. The thin-film transistor substrate according to claim 1, further comprising
a pixel electrode connected to the first thin-film transistor,
wherein
the first thin-film transistor and the pixel electrode constitute a pixel part, and
the second thin-film transistor constitutes a drive circuit that drives the first thin-film transistor.

18. A liquid crystal display comprising
a thin-film transistor substrate according to claim 17; and
a counter substrate that faces the thin-film transistor via a liquid crystal layer.
